(19) United States
(12) Patent Application Publication
(10) Pub. No.: US 2026/0190842 A1
(43) Pub. Date: Jul. 2, 2026

(54) Light Emitting Display Apparatus

(71) Applicant: LG Display Co., Ltd., Seoul (KR)

(72) Inventors: JiYoung Ahn, Paju-si (KR); KyungYun Kang, Paju-si (KR); AhnKi Kim, Paju-si (KR); Hyeonjeong Shin, Paju-si (KR)

(21) Appl. No.: 19/419,828

(22) Filed: Dec. 15, 2025

(30) Foreign Application Priority Data
Dec. 30, 2024 (KR) 10-2024-0201449

(51) Int. Cl. H10K 59/80; H10K 59/124; H10K 59/35; H10K 59/38; H10K 59/50

(52) U.S. Cl. CPC H10K 59/8793; H10K 59/124; H10K 59/351; H10K 59/38; H10K 59/50; H10K 59/8792

(57) ABSTRACT

A light emitting display apparatus according to one or more embodiments of the present disclosure may include a substrate including a plurality of subpixels having an emission area and a non-emission area, a pixel circuit disposed in the non-emission area on the substrate, at least one insulating layer disposed on the pixel circuit, a planarization layer disposed on the at least one insulating layer, and a low-reflection optical pattern portion disposed on the planarization layer in the non-emission area. The low-reflection optical pattern includes a first optical pattern layer made of a first material and a second optical pattern layer made of a second material different from the first material.

### CROSS-REFERENCE TO RELATED APPLICATION

The present application claims priority to Republic of Korea Patent Application No. 10-2024-0201449 filed on Dec. 30, 2024, which is incorporated herein by reference in its entirety.

### BACKGROUND

### Field

The present disclosure relates to a light emitting display apparatus.

### Discussion of Related Art

With the advancement of the information age, the demand for a display apparatus for displaying an image has increased in various forms. Therefore, various types of display apparatuses such as a liquid crystal display (LCD) apparatus, an organic light emitting display (OLED) apparatus, a micro light emitting diode (LED) display apparatus and a quantum dot display (QD) apparatus have been recently used.

Among display apparatuses, the organic light emitting display apparatus is a self-luminance type. In the organic light emitting display apparatus, hole and electron are injected into an emission layer from an anode electrode for hole injection and a cathode electrode for electron injection, and the injected hole and electron are bonded to each other. Herein, the bonded hole and electron exciton fall from the excited state to the ground state, the organic light emitting display apparatus may emit light and display an image.

Such the organic light emitting display apparatus has primarily employed a polarizer on a display surface of a panel to reduce external light reflection. However, when the organic light emitting display apparatus uses a polarizer, transmittance decreases, thereby reducing panel efficiency and increasing power consumption.

### SUMMARY

One or more embodiments of the present disclosure may provide a light emitting display apparatus capable of reducing reflection caused by external light and improving light extraction efficiency.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

A light emitting display apparatus according to one or more embodiments of the present disclosure may include a substrate including a plurality of subpixels having an emission area and a non-emission area, a pixel circuit disposed in the non-emission area on the substrate, at least one insulating layer disposed on the pixel circuit, a planarization layer disposed on the at least one insulating layer, and a low-reflection optical pattern portion disposed on the planarization layer in the non-emission area and including a first optical pattern layer and a second optical pattern layer made of a material different from that of the first optical pattern layer.

According to one or more embodiments of the present disclosure, a light emitting display apparatus capable of reducing reflection caused by external light and improving light extraction efficiency may be provided.

The light emitting display apparatus according to one or more embodiments of the present disclosure may reduce reflection caused by external light and improve light extraction efficiency, and thus may reduce power consumption to enable low-power driving and reduce production energy to achieve an ESG (Environmental, Social, Governance) effect.

The effects of the present disclosure are not limited to the aforesaid, but other effects not described herein will be clearly understood by those skilled in the art from the following descriptions.

The details of the present disclosure described in technical problem, technical solution, and advantageous effects do not specify essential features of claims, and thus, the scope of claims is not limited by the details described in detailed description of the invention.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain the principles and examples of the disclosure.

FIG. 1 illustrates a light emitting display apparatus according to one or more embodiments of the present disclosure.

FIG. 2 is a circuit diagram illustrating a subpixel of a light emitting display apparatus according to one or more embodiments of the present disclosure.

FIG. 3 illustrates a plurality of subpixels in a display panel according to one or more embodiments of the present disclosure.

FIG. 4 is a cross-sectional view taken along line I-I′ of FIG. 3 according to one or more embodiments of the present disclosure.

FIG. 5 illustrates a plurality of subpixels in a display panel according to one or more other embodiments of the present disclosure.

FIG. 6 is a cross-sectional view taken along line II-II′ of FIG. 5 according to one or more other embodiments of the present disclosure.

FIG. 7 illustrates a plurality of subpixels in a display panel according to one or more other embodiments of the present disclosure.

FIG. 8 illustrates a plurality of subpixels in a display panel according to one or more other embodiments of the present disclosure.

FIGS. 9 to 16 illustrate a method of manufacturing a low-reflection optical pattern portion in a display panel according to one or more embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “comprise,” “constitute,” “made of,” “formed of,” or the like is used with respect to one or more elements, one or more other elements may be added unless a term such as “only” or the like is used. The terms used in the present disclosure are merely used in order to describe example embodiments, and are not intended to limit the scope of the present disclosure. The terms of a singular form may include plural forms unless the context clearly indicates otherwise.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

Features of various embodiments of the present disclosure may be partially or entirety coupled to or combined with each other, may be technically associated with each other, and may be variously inter-operated, linked or driven together. The embodiments of the present disclosure may be implemented or carried out independently of each other, or may be implemented or carried out together in a co-dependent or related relationship. In one or more aspects, the components of each apparatus according to various embodiments of the present disclosure are operatively coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

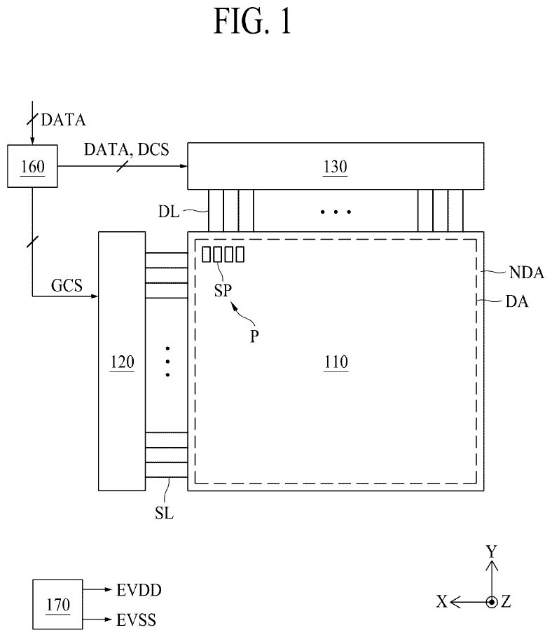

FIG. 1 illustrates a light emitting display apparatus according to one or more embodiments of the present disclosure.

Hereinafter, an X-axis represents a direction parallel to a scan line, a Y-axis represents a direction parallel to a data line, and a Z-axis represents a height direction of the light emitting display apparatus.

A light emitting display apparatus according to one or more embodiments of the present disclosure is implemented as an organic light emitting display apparatus, but may also be implemented as a liquid crystal display apparatus, a quantum dot lighting emitting diode display apparatus, or an electrophoretic display apparatus.

Referring to FIG. 1, the light emitting display apparatus according to one or more embodiments of the present disclosure may include a display panel 110, a scan driver 120 (or a gate driver) embedded in the display panel 110, a data driver 130 connected to the display panel 110, a timing controller 160 controlling the scan driver 120 and the data driver 130, and a power circuit 170.

The display panel 110 includes a display area DA and a non-display area NDA surrounding the display area DA. The display panel 110 includes pixels P provided in the display area DA to display an image. Each of the pixels P may include a plurality of subpixels SP. The structure of the subpixel SP may be variously changed according to the type of the light emitting display apparatus. For example, the subpixels SP may be formed in a top emission type, a bottom emission type, or a dual emission type according to the structure. The subpixels SP indicate a unit capable of forming a color filter of a specific type or capable of emitting a color of itself without forming a color filter. The subpixels SP may have one or more other light-emitting areas according to light-emitting characteristics. For example, the plurality of subpixels SP may be arranged in a stripe type or a quad type, but embodiments of the present disclosure are not limited thereto. The color type, arrangement type, arrangement order, and the like of the subpixels SP may be configured in various forms according to the light-emitting characteristics, lifespan of the apparatus, spec of the apparatus, and the like.

The display panel 110 may include data lines DL and scan lines SL (or gate lines) connected to the subpixels SP. The data lines DL may be arranged to cross the scan lines SL. Each of the subpixels SP of the display panel 110 may be connected to any one of the data lines DL and any one of the scan lines SL. The data lines DL may supply a data voltage supplied from the data driver 130 to each of the subpixels SP. The scan lines SL may supply a scan signal supplied from the scan driver 120 to each of the subpixels SP

Each of the subpixels SP is turned-on by the scan signal. When the data voltage of the data line DL is supplied to a gate electrode of a driving transistor, a light emitting element may emit light according to a drain-to-source current of the driving transistor. The scan driver 120 may receive a scan control signal GCS from the timing controller 160. The scan driver 120 may supply the scan signals or emission control signal to the scan lines SL by using the scan control signal GCS.

The scan driver 120 may be configured in a gate driver in panel GIP manner in the non-display area NDA outside one side or both sides of the display area DA. Alternatively, the scan driver 120 may be manufactured as a driving chip, mounted on a flexible film, and attached to the non-display area NDA outside one side or both sides of the display area DA in a tape automated bonding TAB manner.

The data driver 130 may receive digital video data DATA and a data control signal DCS from the timing controller 160. The data driver 130 converts the digital video data DATA into analog positive/negative data voltages by using the data control signal DCS and supplies the analog positive/negative data voltages to the data lines DL.

The timing controller 160 receives digital video data DATA and timing signals from a host system. The timing signals may include a vertical synchronization signal, a horizontal synchronization signal, a data enable signal, a dot clock, and the like. The vertical synchronization signal is a signal defining one frame period. The horizontal synchronization signal is a signal defining one horizontal period required for supplying the data voltages to the pixels of one horizontal line of the display panel 110. The data enable signal defines a period in which valid data is input. The dot clock is a signal repeated at a predetermined short period.

The timing controller 160 may generate the data control signal DCS for controlling an operation timing of the data driver 130 and the scan control signal GCS for controlling an operation timing of the scan driver 120 based on the timing signals. The timing controller 160 may output the scan control signal GCS to the scan driver 120 to control the scan driver 120 and output the digital video data DATA and data control signal DCS to the data driver 130 to control the data driver 130.

The power circuit 170 may generate and supply a plurality of driving voltages required for an operation of all circuit configurations of the light emitting display apparatus by using an input voltage. The power circuit 170 may generate a first power source voltage EVDD (or pixel power voltage), a second power supply voltage EVSS (or common power voltage) and an initialization voltage Vref (or reference voltage) and supply the generated voltages to the display panel 110. The power circuit 170 may generate and supply various driving voltages required for operations of the scan driver 120, the data driver 130, and the timing controller 160.

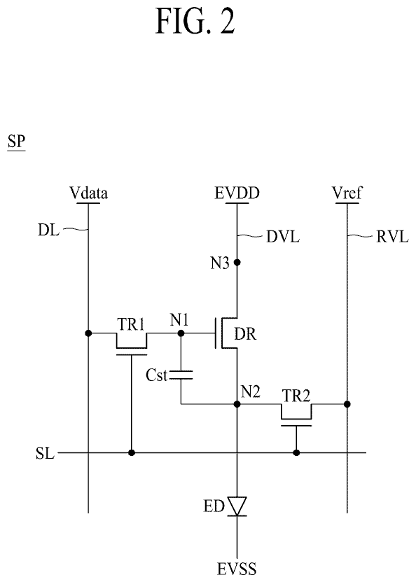

FIG. 2 is a circuit diagram illustrating a subpixel of a light emitting display apparatus according to one or more embodiments of the present disclosure.

Referring to FIG. 2, each of pixels P includes the plurality of subpixels SP constituting a unit pixel. In each of the plurality of subpixels SP, there are a pixel circuit having 3T (Transistor) 1C (Capacitor) including the driving transistor DR, the first switching transistor TR1, the second switching transistor TR2 and the storage capacitor Cst, and the light emitting device ED, but not limited thereto. Each subpixel SP may further include a compensation circuit. In this case, the subpixel SP may have various structures such as 3T2C, 4T1C, 4T2C, 5T1C, 5T2C, 6T1C, 6T2C, 7T1C, and 7T2C.

At least one thin film transistor DR, TR1 and TR2 of each subpixel SP may include a gate electrode, a source electrode, and a drain electrode. Since the source electrode and the drain electrode may be changed according to a voltage and a current direction applied to the gate electrode without being fixed, any one of the source electrode and the drain electrode may be represented as a first electrode, and the other may be represented as a second electrode. The at least one transistor DR, TR1, and TR2 may use at least one of polysilicon semiconductor, amorphous silicon semiconductor, and oxide semiconductor. The transistors DR, TR1, and TR2 may be P-type or N-type, or P-type and N-type may be interchangeably used.

The driving transistor DR corresponds to a transistor for driving the light emitting device ED, and the driving transistor DR includes the first node N1 to which the data voltage Vdata is applied, the second node N2 connected to a pixel electrode (first electrode or anode electrode) of the light emitting device ED, and the third node N3 connected to the first power voltage line DVL (or pixel power voltage line) and supplied with the first power voltage EVDD (or pixel power voltage). For example, the driving transistor DR may generate a data current from the first power voltage EVDD supplied from the first power voltage line DVL and may supply the data current to the first electrode of the light emitting device ED.

The first switching transistor TR1 may serve to supply the data voltage Vdata supplied from the data line DL to the first node N1 of the driving transistor DR. The second switching transistor TR2 may serve to supply the reference voltage Vref supplied from the reference line REFL to the second node N2 of the driving transistor DR or may output a voltage of the second node N2 of the driving transistor DR. The storage capacitor Cst may be connected between the first node N1 and the second node N2 of the driving transistor DR. The storage capacitor Cst may serve to maintain the data voltage Vdata supplied to the driving transistor DR for one frame, but embodiments of the present disclosure are not limited thereto.

The light emitting device ED may include the pixel electrode (first electrode or anode electrode) connected to the second node N2 of the driving transistor DR, and a second power voltage (EVSS) (or a common power voltage) may be applied to a common electrode (a second electrode or a cathode electrode). The light emitting device ED may emit light in response to a driving current generated by the driving transistor DR through an emission layer (or organic emission layer) between the first electrode and the second electrode. The pixel electrode of the light emitting device ED may be an independent electrode for each light emitting device, and the common electrode and the emission layer of the light-emitting device ED may be a common layer shared by the entire light emitting devices, but embodiments of the present disclosure are not limited thereto.

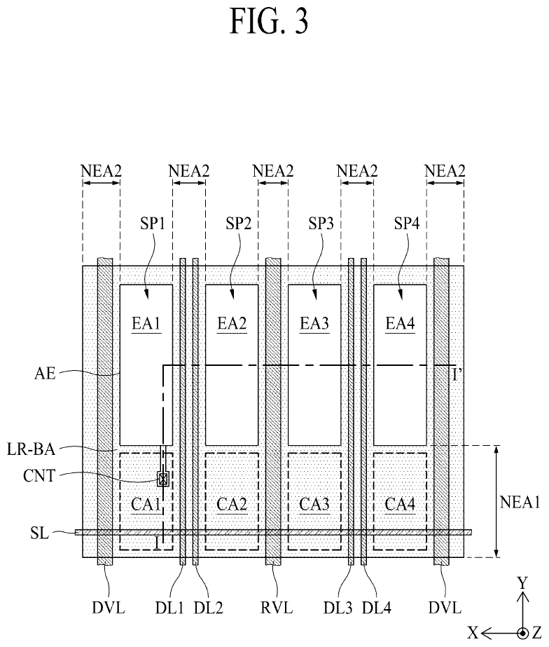

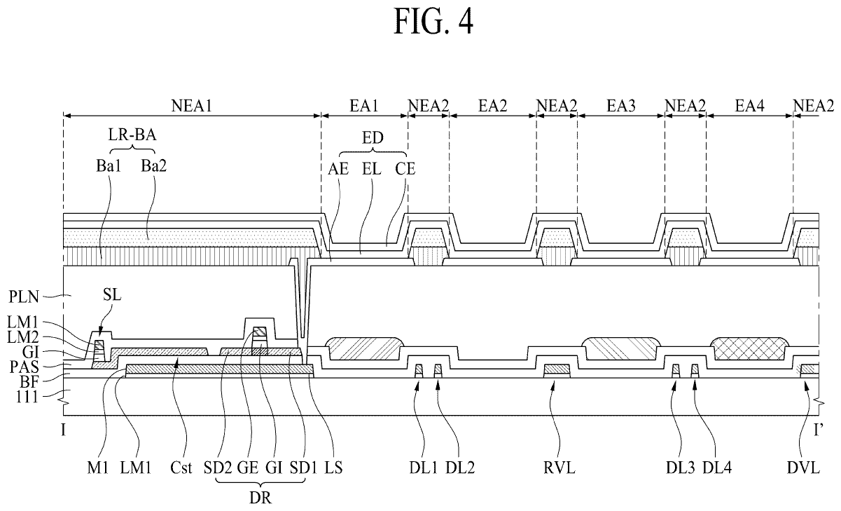

FIG. 3 illustrates a plurality of subpixels in a display panel according to one or more embodiments of the present disclosure. FIG. 4 is a cross-sectional view taken along line I-I′ of FIG. 3 according to one or more embodiments of the present disclosure.

Referring to FIGS. 3 and 4, the display panel 110 according to one or more embodiments of the present disclosure may be configured to a top emission type, a bottom emission type, or a dual emission type. For example, the display panel 110 may be implemented in the bottom emission type, but the embodiments of the present disclosure are not limited thereto.

The display panel 110 according to one or more embodiments of the present disclosure may include a plurality of subpixels SP1, SP2, SP3 and SP4, a plurality of data lines DL1, DL2, DL3 and DL4, at least one scan line SL (or gate line), a first power voltage line DVL, a reference voltage line RVL, pixel circuits CA1, CA2, CA3 and CA4, at least one color filter CF1, CF3 and CF4, and a low-reflection optical pattern portion LR-BA.

The plurality of subpixels SP1, SP2, SP3 and SP4 may be unit pixels that different colors. The plurality of subpixels SP1, SP2, SP3 and SP4 may be arranged in a stripe type in a first direction (or X-axis direction) or a second direction (or Y-axis direction). For example, the plurality of subpixels SP1, SP2, SP3 and SP4 may be arranged in the first direction (or X-axis direction), but not limited thereto. The arrangement order or type of the plurality of subpixels may be variously changed.

The plurality of subpixels SP1, SP2, SP3 and SP4 may include emission areas EA1, EA2, EA3 and EA4 in which the light emitting element ED configured to emit light is disposed, the light emitting element ED including a pixel electrode AE, an emission layer EL and a common electrode CE, and a non-emission area NEA. For example, the non-emission area NEA may include a first non-emission area NEA1 in which pixel circuits CA1, CA2, CA3 and CA4 are disposed, and a second non-emission area NEA2 between adjacent subpixels SP1, SP2, SP3 and SP4. For example, the pixel circuit CA1, CA2, CA3 and CA4 of each of the subpixels SP1, SP2, SP3 and SP4 may include at least one thin-film transistor DR, TR1 and TR2 and a storage capacitor Cst, but embodiments of the present disclosure are not limited thereto.

The display panel 110 according to one or more embodiments of the present disclosure may be implemented in a bottom emission type, and the emission area EA1, EA2, EA3 and EA4 of each of the subpixels SP1, SP2, SP3 and SP4 and the first non-emission area NEA1 in which pixel circuits CA1, CA2, CA3 and CA4 are disposed may not overlap with each other or may at least partially overlap with each other. For example, the emission areas EA1, EA2, EA3 and EA4 may be disposed on an upper side in the second direction (or a Y-axis direction), and the first non-emission area NEA1 may be disposed on a lower side in the second direction, but embodiments of the present disclosure are not limited thereto.

In the first non-emission area NEA1, at least one scan line SL extending in the first direction (or an X-axis direction) may be disposed, and in the second non-emission area NEA2, one or more voltage signal lines extending in the second direction (or a Y-axis direction) may be disposed. For example, the one or more voltage signal lines may include the plurality of data lines DL1, DL2, DL3 and DL4, at least one reference voltage line RVL, and at least one first power voltage line DVL (or driving power voltage line).

The display panel 110 according to one or more embodiments of the present disclosure may include a low-reflection optical pattern portion LR-BA disposed in the non-emission area NEA of each of the subpixels SP1, SP2, SP3 and SP4. The low-reflection optical pattern portion LR-BA may include a first optical pattern layer Ba1 having a linear polarization characteristic and a second optical pattern layer Ba2 having a phase retardation characteristic. For example, the low-reflection optical pattern portion LR-BA may implement a circular polarization characteristic capable of effectively preventing reflection of external light due to different optical characteristics of the first and second optical pattern layers Ba1 and Ba2. Details of the first and second optical pattern layers Ba1 and Ba2 of the low-reflection optical pattern portion LR-BA will be described later with reference to FIG. 4.

The low-reflection optical pattern portion LR-BA may be configured to cover the non-emission area NEA of each of the subpixels SP1, SP2, SP3 and SP4. For example, the low-reflection optical pattern portion LR-BA may be a bank portion defining the emission areas EA1, EA2, EA3 and EA4 of each of the subpixels SP1, SP2, SP3 and SP4. The low-reflection optical pattern portion LR-BA may be disposed to surround a periphery of the emission areas EA1, EA2, EA3 and EA4 of each of the subpixels SP1, SP2, SP3 and SP4.

The low-reflection optical pattern portion LR-BA may be disposed to overlap the pixel circuits CA1, CA2, CA3 and CA4 in the first non-emission area NEA1. The low-reflection optical pattern portion LR-BA may cover an edge portion of the pixel electrode AE of each of the subpixels SP1, SP2, SP3 and SP4 in the first non-emission area NEA1, and may be disposed on a planarization layer PLN overlapping the pixel circuits CA1, CA2, CA3 and CA4 where the pixel electrode AE is not disposed. For example, the low-reflection optical pattern portion LR-BA may be disposed between the planarization layer PLN and the emission layer EL in the first non-emission area NEA1. In addition, the low-reflection optical pattern portion LR-BA may be configured to cover a contact portion CNT in which the pixel electrode AE of each of the subpixels SP1, SP2, SP3 and SP4 and a second node N2 (or a source electrode) of a driving transistor DR of each of the pixel circuits CA1, CA2, CA3 and CA4 are electrically connected.

The low-reflection optical pattern portion LR-BA may cover an edge portion of the pixel electrode AE of adjacent subpixels SP1, SP2, SP3 and SP4 in the second non-emission area NEA2, and may define an opening area (or an emission area) of each of the pixel electrodes AE. The low-reflection optical pattern portion LR-BA may be disposed to overlap the plurality of data lines DL1, DL2, DL3 and DL4, at least one reference voltage line RVL, and at least one first power voltage line DVL in the second non-emission area NEA2. For example, the low-reflection optical pattern portion LR-BA may be disposed between the edge portion of the pixel electrode AE and the emission layer EL in the second non-emission area NEA2.

The emission areas EA1, EA2, EA3 and EA4 may correspond to regions in which light is emitted in each of the subpixels SP1, SP2, SP3 and SP4. For example, each of the subpixels SP1, SP2, SP3 and SP4 may include the light emitting element ED configured by overlapping the pixel electrode AE, the emission layer EL and the common electrode CE, and the emission areas EA1, EA2, EA3 and EA4 may correspond to the light emitting element ED of each of the subpixels SP1, SP2, SP3 and SP4. For example, the emission areas EA1, EA2, EA3 and EA4 may correspond to an area of the opening area of the pixel electrode AE defined by the low-reflection optical pattern portion LR-BA.

The emission areas EA1, EA2, EA3 and EA4 may include first to fourth emission areas EA1, EA2, EA3 and EA4 that emit light of different colors. For example, the emission areas EA1, EA2, EA3 and EA4 may overlap at least one color filter CF1, CF3 and CF4 and may emit light of different colors therethrough.

The at least one color filter CF1, CF3 and CF4 may emit light of different colors. For example, the at least one color filter CF1, CF3 and CF4 may be formed of an organic material that transmits light of different colors. The at least one color filter CF1, CF3 and CF4 may include a first color filter CF1 that transmits red light, a third color filter CF3 that transmits blue light, and a fourth color filter CF4 that transmits green light.

A first emission area EA1 of a first subpixel SP1 may emit red light through a first color filter CF1, a second emission area EA2 of a second subpixel SP2 may emit white light without a color filter or through a color filter that transmits white light, a third emission area EA3 of a third subpixel SP3 may emit blue light through a third color filter CF3, and a fourth emission area EA4 of a fourth subpixel SP4 may emit green light through a fourth color filter CF4, but embodiments of the present disclosure are not limited thereto.

The at least one scan line SL (or gate line) may be disposed to overlap the first non-emission area NEA1 where the pixel circuits CA1, CA2, CA3 and CA4 are disposed. The at least one scan line SL may extend in the first direction (or X-axis direction) to cross the first non-emission area NEA1. The at least one scan line SL may supply a scan signal to at least one thin film transistor TR1 and TR2 included in the pixel circuits CA1, CA2, CA3 and CA4. For example, the at least one scan line SL may be formed of the same material in the same layer as a gate electrode of the at least one thin film transistor DR, TR1 and TR2 disposed in the pixel circuits CA1, CA2, CA3 and CA4. For example, the at least one scan line SL may include a low-reflection material layer to reduce reflection of external light. Also, the at least one scan line SL may include a plurality of scan lines SL for applying separate scan signals to first and second switching transistors TR1 and TR2 of the pixel circuits CA1, CA2, CA3 and CA4, but the embodiments of the present disclosure are not limited thereto.

The plurality of data lines DL1, DL2, DL3 and DL4 may be disposed to correspond to each subpixel SP1, SP2, SP3 and SP4. The plurality of data lines DL1, DL2, DL3 and DL4 may be disposed between the plurality of subpixels SP1, SP2, SP3 and SP4. For example, the plurality of data lines DL1, DL2, DL3 and DL4 may be disposed to overlap the second non-emission area NEA2 between adjacent subpixels SP1, SP2, SP3 and SP4. The plurality of data lines DL1, DL2, DL3 and DL4 may extend in the second direction (or Y-axis direction) in the second non-emission area NEA2. For example, each data line DL1, DL2, DL3 and DL4 may be formed of the same material in the same layer as a light blocking layer disposed in a pixel circuit. Each data line DL1, DL2, DL3 and DL4 may include a low-reflection material layer to reduce reflection of external light.

The first and second data lines DL1 and DL2 may extend in the second direction (or Y-axis direction) in the second non-emission area NEA2 between the first subpixel SP1 and the second subpixel SP2. The first data line DL1 may be disposed on a right side of the first subpixel SP1 to supply a data voltage to the first subpixel SP1, and the second data line DL2 may be disposed on a left side of the second subpixel SP2 to supply a data voltage to the second subpixel SP2.

The third and fourth data lines DL3 and DL4 may extend in the second direction (or Y-axis direction) in the second non-emission area NEA2 between the third subpixel SP3 and the fourth subpixel SP4. The third data line DL3 may be disposed on a right side of the third subpixel SP3 to supply a data voltage to the third subpixel SP3, and the fourth data line DL4 may be disposed on a left side of the fourth subpixel SP4 to supply a data voltage to the fourth subpixel SP4.

The at least one first power voltage line DVL (or driving power voltage line) may be disposed to correspond to the plurality of subpixels SP1, SP2, SP3 and SP4. The at least one first power voltage line DVL may be disposed on a left side or a right side of the plurality of subpixels SP1, SP2, SP3 and SP4. For example, the at least one first power voltage line DVL may be disposed on a left side of the first subpixel SP1 and may be disposed to overlap the second non-emission area NEA2 between the first subpixel SP1 and a fourth subpixel SP4 of another pixel P adjacent to the first subpixel SP1. Also, the at least one first power voltage line DVL may be disposed on a right side of the fourth subpixel SP4 and may be disposed to overlap the second non-emission area NEA2 between the fourth subpixel SP4 and a first subpixel SP1 of another pixel P adjacent to the fourth subpixel SP4. The at least one first power voltage line DVL may extend in the second direction (or Y-axis direction) in the second non-emission area NEA2 between adjacent pixels P. For example, the first power voltage line DVL may be formed of the same material in the same layer as the plurality of data lines DL1, DL2, DL3 and DL4, but the embodiments of the present disclosure are not limited thereto.

The reference voltage line RVL may be disposed to correspond to the plurality of subpixels SP1, SP2, SP3 and SP4. The reference voltage line RVL may be disposed within the plurality of subpixels SP1, SP2, SP3 and SP4. The reference voltage line RVL may be disposed between the second subpixel SP2 and the third subpixel SP3. The reference voltage line RVL may extend in the second direction (or Y-axis direction) in the second non-emission area NEA2 between the second subpixel SP2 and the third subpixel SP3. For example, the reference voltage line RVL may be formed of the same material in the same layer as the plurality of data lines DL1, DL2, DL3 and DL4 and/or the first power voltage line DVL, but the embodiments of the present disclosure are not limited thereto.

Referring to FIG. 4, the display panel 110 according to one or more embodiments of the present disclosure may include a substrate 111, the plurality of data lines DL1, DL2, DL3 and DL4, the at least one first power voltage line DVL, the reference voltage line RVL, the at least one insulating layer BF, GI and PAS, the at least one color filter CF1, CF3 and CF4, the planarization layer PLN, the pixel electrode AE, the emission layer EL, the common electrode CE, and the low-reflection optical pattern portion LR-BA. For example, the low-reflection optical pattern portion LR-BA may be disposed on the planarization layer PLN and the pixel electrode AE, and may be configured to define the opening area (or emission area) of the pixel electrode AE of each of the subpixels SP1, SP2, SP3 and SP4.

The at least one voltage signal line may be disposed on the substrate 111. For example, the plurality of data lines DL1, DL2, DL3 and DL4, the at least one first power voltage line DVL, and the reference voltage line RVL may be disposed on the substrate 111. For example, the plurality of data lines DL1, DL2, DL3 and DL4, the at least one first power voltage line DVL, and the reference voltage line RVL may be formed of the same material in the same layer as a light blocking layer disposed in pixel circuits CA1, CA2, CA3 and CA4, but embodiments of the present disclosure are not limited thereto.

The at least one of the plurality of data lines DL1, DL2, DL3 and DL4, the at least one first power voltage line DVL, and the reference voltage line RVL disposed at a lowermost portion of the substrate 111 may include a low-reflection material for reducing external light reflection. For example, the voltage signal lines DL, DVL and RVL may include a metal layer M1 and a low-reflection material layer LM1. The low-reflection material layer LM1 may be disposed below the metal layer M1. The metal layer M1 of the voltage signal lines DL, DVL and RVL may be formed as a single layer or a multilayer of at least one selected from molybdenum (Mo), aluminum (Al), chromium (Cr), tungsten (W), gold (Au), titanium (Ti), nickel (Ni), neodymium (Nd), and copper (Cu), but embodiments of the present disclosure are not limited thereto. The low-reflection material layer LM1, which is a metal layer having excellent low-reflection characteristics, may be formed of molybdenum-titanium (MoTi) or molybdenum (Mo), or may include a metal oxide or an alloy oxide. For example, the low-reflection material layer LM1 may include copper oxide (CuOx), nickel oxide (NiOx), molybdenum oxide (MoOx), or tungsten oxide (WOx), but embodiments of the present disclosure are not limited thereto. For example, at least one of the plurality of data lines DL1, DL2, DL3 and DL4, the at least one first power voltage line DVL, and the reference voltage line RVL may have a double-layer structure formed of copper (Cu) and molybdenum-titanium (MoTi), or of copper (Cu) and tungsten oxide (WOx).

The at least one insulating layer BF, GI and PAS may be disposed on the substrate 111. The at least one insulating layer BF, GI and PAS may be configured to protect pixel circuits CA1, CA2, CA3 and CA4 disposed in the non-emission area NEA on the substrate 111. For example, the at least one insulating layer BF, GI and PAS may include a buffer layer BF, a gate insulating layer GI, and a passivation layer PAS. For example, the at least one insulating layer BF, GI and PAS may be formed as a single layer or a multilayer including an inorganic insulating material such as silicon oxide (SiOX), silicon nitride (SiNX), or aluminum oxide (Al2O3), but embodiments of the present disclosure are not limited thereto.

The buffer layer BF may be disposed on the substrate 111. The buffer layer BF may be configured to cover the at least one voltage signal line DL, DVL and RVL and a light blocking layer LS on the substrate 111. For example, the buffer layer BF may be disposed over the entire surface of the substrate 111, and the pixel circuits CA1, CA2, CA3 and CA4 may be disposed on the buffer layer BF. For example, each of the pixel circuits CA1, CA2, CA3 and CA4 may include the at least one thin film transistor DR and the storage capacitor Cst. The buffer layer BF may serve to protect the at least one voltage signal line DL, DVL and RVL and the pixel circuits CA1, CA2, CA3 and CA4 from foreign substances or moisture penetrating through the substrate 111.

The gate insulating layer GI, the passivation layer PAS, the thin film transistor DR, and the storage capacitor Cst may be disposed on the buffer layer BF. An active layer ACT forming the thin film transistor DR and the storage capacitor Cst may be disposed on the buffer layer BF. The gate insulating layer GI may be disposed on the active layer ACT, a gate electrode GE may be formed on the gate insulating layer GI, and the passivation layer PAS may be disposed on the gate electrode GE and the active layer ACT. For example, the thin film transistor DR may include the active layer ACT, the gate insulating layer GI, the gate electrode GE, and source and drain electrodes SD1 and SD2. For example, the source and drain electrodes SD1 and SD2 may be formed of a conductive active layer ACT, but embodiments of the present disclosure are not limited thereto. In addition, the storage capacitor Cst may have a capacitance structure including a first electrode formed of the same material as the light blocking layer LS and a second electrode formed of a conductive active layer ACT, but embodiments of the present disclosure are not limited thereto.

The active layer ACT may be disposed on the buffer layer BF and may include a semiconductor material based on an oxide semiconductor such as indium gallium zinc oxide (IGZO), or a semiconductor material based on silicon such as amorphous silicon or polycrystalline silicon, but embodiments of the present disclosure are not limited thereto. The active layer ACT may include a source region, a drain region, and a channel region between the source and drain regions.

The gate insulating layer GI may be patterned and formed on a channel region of the active layer ACT, or may be patterned and formed together with the gate electrode GE, or may be disposed over the entire surface of the buffer layer BF, but embodiments of the present disclosure are not limited thereto.

The gate electrode GE may be disposed on the gate insulating layer GI so as to overlap the channel region of the active layer ACT, and may be patterned together with the gate insulating layer GI. The gate electrode GE may be formed of the same material in the same layer as at least one scan line SL (or gate line).

The gate electrode GE and the at least one scan line SL may include a low-reflection material layer for reducing external light reflection. For example, the gate electrode GE and the at least one scan line SL may include a conductive metal layer M2 and a low-reflection material layer LM2 below the metal layer M2. For example, the metal layer M2 may be formed as a single layer or a multilayer of at least one selected from molybdenum (Mo), aluminum (Al), chromium (Cr), tungsten (W), gold (Au), titanium (Ti), nickel (Ni), neodymium (Nd), and copper (Cu), but embodiments of the present disclosure are not limited thereto. The low-reflection material layer LM2, which is a metal layer having excellent low-reflection characteristics, may be formed of molybdenum-titanium (MoTi) or molybdenum (Mo), or may include a metal oxide or an alloy oxide. For example, the low-reflection material layer LM2 may include copper oxide (CuOx), nickel oxide (NiOx), molybdenum oxide (MoOx), or tungsten oxide (WOx), but embodiments of the present disclosure are not limited thereto. For example, the gate electrode GE and the at least one scan line SL may have a double-layer structure formed of copper (Cu) and molybdenum-titanium (MoTi), or of copper (Cu) and a metal oxide.

The passivation layer PAS may be configured to cover the gate electrode GE and the active layer ACT on the buffer layer BF. The passivation layer PAS may be disposed over the entire surface of the buffer layer BF. The at least one color filter CF1, CF3 and CF4 may be disposed on the passivation layer PAS. The at least one color filter CF1, CF3 and CF4 may be disposed to correspond to the first, third, and fourth subpixels SP1, SP3 and SP4 among the first to fourth subpixels SP1, SP2, SP3 and SP4. A color filter may not be disposed in the second subpixel SP2 among the first to fourth subpixels SP1, SP2, SP3 and SP4. For example, a first color filter CF1 that converts white light emitted from a light emitting device ED into red light may be disposed in a first emission area EA1 of the first subpixel SP1. No color filter may be disposed in a second emission area EA2 of the second subpixel SP2, and white light emitted from the light emitting device ED may be emitted as it is. A third color filter CF3 that converts white light emitted from the light emitting device ED into blue light may be disposed in a third emission area EA3 of the third subpixel SP3. A fourth color filter CF4 that converts white light emitted from the light emitting device ED into green light may be disposed in a fourth emission area EA4 of the fourth subpixel SP4.

The planarization layer PLN (or overcoat layer) may be disposed on the passivation layer PAS and the at least one color filter CF1, CF3 and CF4. The planarization layer PLN may be formed of an organic insulating material to planarize a level difference caused by pixel circuits CA1, CA2, CA3 and CA4, the at least one voltage signal line DL, DVL and RVL, and the at least one color filter CF1, CF3 and CF4 disposed on the substrate 111. For example, the planarization layer PLN may be formed of an organic material such as an acryl resin, an epoxy resin, a phenolic resin, a polyamide resin, or a polyimide resin, but embodiments of the present disclosure are not limited thereto.

The pixel electrode AE (first electrode or anode electrode), the emission layer EL (or organic emission layer), and the common electrode CE (second electrode or cathode electrode) forming the light emitting device ED may be disposed on the planarization layer PLN. According to one or more embodiments of the present disclosure, the low-reflection optical pattern portion LR-BA may be disposed in the non-emission area NEA on the planarization layer PLN.

The pixel electrode AE may be disposed on the planarization layer PLN. The pixel electrode AE may be patterned and disposed on the planarization layer PLN for each of the subpixels SP1, SP2, SP3 and SP4.

The pixel electrode AE may be formed of a transparent metal material or a semi-transmissive metal material. For example, the pixel electrode AE may be formed of a transparent conductive material (TCO) such as indium tin oxide (ITO) or indium zinc oxide (IZO) capable of transmitting light. The pixel electrode AE may be formed of a semi-transmissive conductive material such as magnesium (Mg), silver (Ag), or an alloy of magnesium (Mg) and silver (Ag). For example, when the pixel electrode AE is formed of a semi-transmissive conductive material, light extraction efficiency may be improved by a microcavity. The pixel electrode AE may serve as an anode electrode of the light emitting device ED. According to one or more embodiments of the present disclosure, the pixel electrode AE may further include a low-reflection metal layer. For example, the low-reflection metal layer, which is a metal layer having excellent low-reflection characteristics, may be formed of molybdenum-titanium (MoTi) or molybdenum (Mo), but embodiments of the present disclosure are not limited thereto.

The low-reflection optical pattern portion LR-BA may be disposed in the non-emission areas NEA of the respective subpixels SP1, SP2, SP3 and SP4. The low-reflection optical pattern portion LR-BA may be disposed on the pixel electrode AE and the planarization layer PLN. The low-reflection optical pattern portion LR-BA may be disposed on the planarization layer PLN so as to cover an edge portion of the pixel electrode AE. The pattern portion LR-BA may cover the edge portion of the pixel electrode AE to define the opening area (or emission area) of the pixel electrode AE. For example, the pattern portion LR-BA may be disposed on the planarization layer PLN to cover an entire first non-emission area NEA1 in which pixel circuits CA1, CA2, CA3 and CA4 are disposed. In the first non-emission area NEA1, the low-reflection optical pattern portion LR-BA may be disposed between the planarization layer PLN and the emission layer EL. In addition, the pattern portion LR-BA may be disposed in the second non-emission area NEA2 between adjacent subpixels SP1, SP2, SP3 and SP4 so as to cover edge portions of the pixel electrodes AE and define the opening areas (or emission areas) of the respective pixel electrodes AE. In the second non-emission area NEA2, the low-reflection optical pattern portion LR-BA may be disposed between the edge portions of the pixel electrodes AE and the emission layer EL.

The emission layer EL (or organic emission layer) may be disposed on the pixel electrode AE and the low-reflection optical pattern portion LR-BA. The emission layer EL may include a hole transporting layer, an emission material layer, and an electron transporting layer. For example, when a voltage is applied between the pixel electrode AE and the common electrode CE, holes and electrons may move to the emission layer EL through the hole transporting layer and the electron transporting layer, respectively, and combine in the emission layer EL to emit light. The emission layer EL may be a common layer formed in common for the plurality of subpixels SP1, SP2, SP3 and SP4. For example, the emission layer EL may be a white emission layer that emits white light.

The common electrode CE may be disposed on the emission layer EL. The common electrode CE may be a common layer formed in common for the plurality of subpixels SP1, SP2, SP3 and SP4. The common electrode CE may be disposed on the pixel electrode AE and the emission layer EL that are in contact with each other to form the light emitting device ED. For example, the common electrode CE may be formed of a highly reflective metal material having a stacked structure such as Ti/Al/Ti (titanium/aluminum/titanium), ITO/Al/ITO (indium tin oxide/aluminum/indium tin oxide), an Ag alloy, ITO/Ag alloy/ITO, a MoTi alloy, or ITO/MoTi alloy/ITO. The Ag alloy may be an alloy of silver (Ag), palladium (Pd), and copper (Cu). The MoTi alloy may be an alloy of molybdenum (Mo) and titanium (Ti). The common electrode CE may serve as a cathode electrode of the light emitting device ED.

According to one or more embodiments of the present disclosure, a transmittance control film may be further included on a rear surface of the substrate 111. For example, the transmittance control film may include at least one of a transparent film and a light absorbing film, but embodiments of the present disclosure are not limited thereto.

The low-reflection optical pattern portion LR-BA according to one or more embodiments of the present disclosure may include a first optical pattern layer Ba1 and a second optical pattern layer Ba2 formed of different materials. The first optical pattern layer Ba1 may be disposed on the planarization layer PLN, and the second optical pattern layer Ba2 may be disposed on the first optical pattern layer Ba1.

The first optical pattern layer Ba1 and the second optical pattern layer Ba2 may be configured to have different optical characteristics from each other. For example, the first optical pattern layer Ba1 and the second optical pattern layer Ba2 may be configured to have different transmission axes.

The first optical pattern layer Ba1 may include an anisotropic material. The first optical pattern layer Ba1 may include a reactive mesogen as the anisotropic material. For example, the first optical pattern layer Ba1 may be formed of a mixture of a reactive mesogen and light blocking particles. For example, the light blocking particles may include a black dye or a dichroic dye. The first optical pattern layer Ba1 may be configured to have linear polarization characteristics. For example, the first optical pattern layer Ba1 may be configured to have a transmission axis of 90°, and may convert light into linear polarized light of 90°. For example, the first optical pattern layer Ba1 may convert external light incident through the substrate 111 into linear polarized light and transmit it.

The second optical pattern layer Ba2 may include an anisotropic birefringent material. The second optical pattern layer Ba2 may include a reactive mesogen as the anisotropic birefringent material. The second optical pattern layer Ba2 may be configured to have a phase retardation characteristic. For example, the second optical pattern layer Ba2 may be configured to have a transmission axis of 45° or 135° (or −45°) and may be a quarter-wave plate (QWP) having a phase retardation value of λ/4. For example, the second optical pattern layer Ba2 may convert linear polarized light that has passed through the first optical pattern layer Ba1 into circular polarized light. In addition, the second optical pattern layer Ba2 may convert circular polarized light into linear polarized light of 0°.

According to one or more embodiments of the present disclosure, the first optical pattern layer Ba1 may convert external light incident through the substrate 111 into linear polarized light, and the second optical pattern layer Ba2 may convert the linear polarized light passing through the first optical pattern layer Ba1 into circular polarized light to prevent external light from being reflected. For example, when unpolarized external light is incident on the first optical pattern layer Ba1 of the low-reflection optical pattern portion LR-BA, the first optical pattern layer Ba1 may convert the incident external light into linear polarized light of 90°, and since the second optical pattern layer Ba2 has a transmission axis of 45° or 135° (or −45°), it may convert the external light that has passed through the first optical pattern layer Ba1 into circular polarized light. The circular polarized external light is reflected by the common electrode CE and then passes through the second optical pattern layer Ba2 again, being converted into linear polarized light of 0°. The external light linearly polarized at 0° has a transmission axis different from that of the first optical pattern layer Ba1 and thus may be mostly absorbed in the first optical pattern layer Ba1. Accordingly, the low-reflection optical pattern portion LR-BA according to one or more embodiments of the present disclosure may reduce reflection of external light.

The low-reflection optical pattern portion LR-BA according to one or more embodiments of the present disclosure may be disposed in the non-emission areas NEA of the respective subpixels SP1, SP2, SP3 and SP4 to define the opening areas (or emission areas) of the pixel electrodes AE of the respective subpixels SP1, SP2, SP3 and SP4. Through this configuration, the low-reflection optical pattern portion LR-BA may reduce external light reflection generated from the pixel circuits CA1, CA2, CA3 and CA4 and various signal voltage lines DL, DVL, RVL and SL by covering entire the first and second non-emission areas NEA1 and NEA2 where external light reflectivity is relatively high. In addition, the low-reflection optical pattern portion LR-BA may not be disposed in the emission areas EA1, EA2, EA3 and EA4 where the at least one color filter CF1, CF3 and CF4 is disposed and external light reflectivity is relatively low, thereby minimizing or at least reducing loss of light emitted from the light emitting device ED and improving light extraction efficiency.

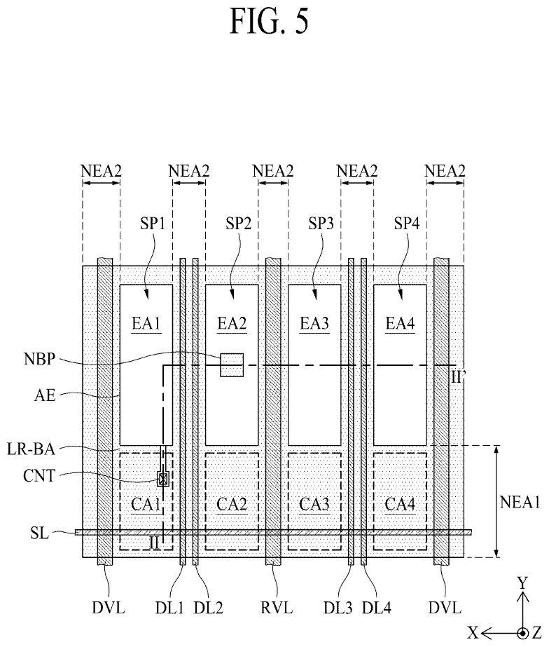

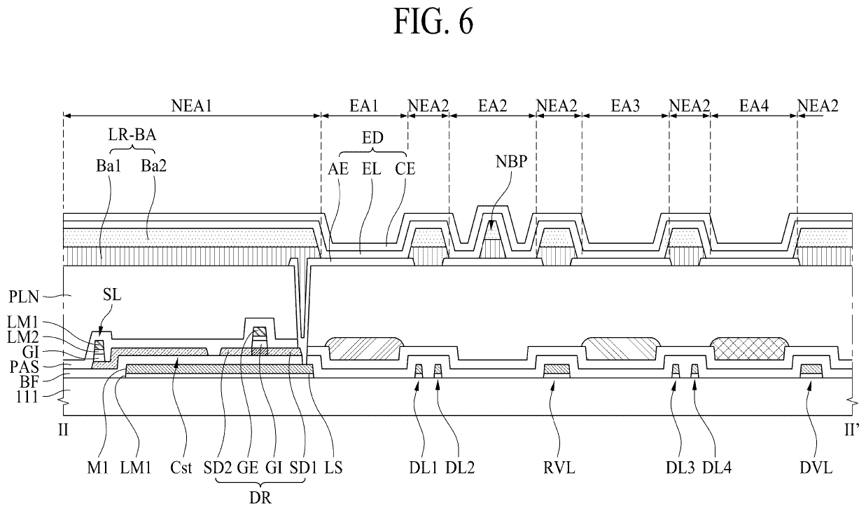

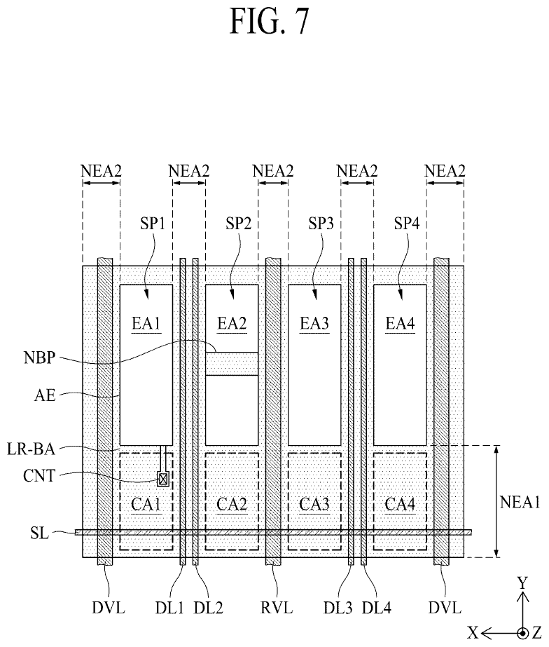

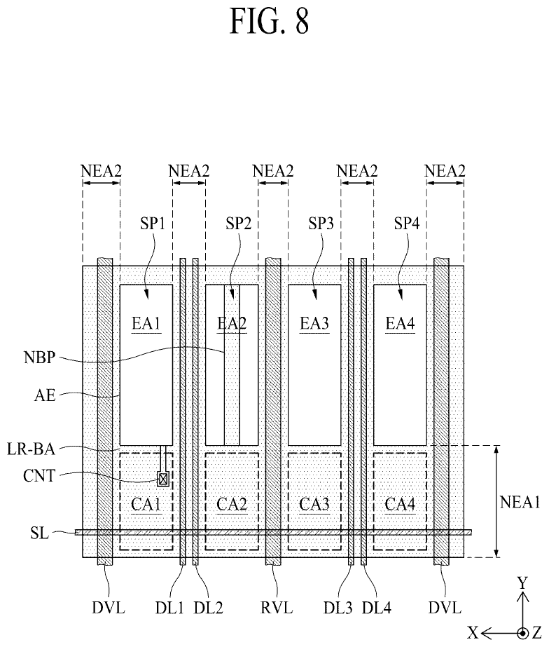

FIG. 5 illustrates a plurality of subpixels in a display panel according to one or more other embodiments of the present disclosure. FIG. 6 is a cross-sectional view taken along line II-II′ of FIG. 5 according to one or more other embodiments of the present disclosure. FIG. 7 illustrates a plurality of subpixels in a display panel according to one or more other embodiments of the present disclosure. FIG. 8 illustrates a plurality of subpixels in a display panel according to one or more other embodiments of the present disclosure. FIGS. 5 to 8 illustrate one or more embodiments in which a non-opening optical pattern is additionally provided in the light emitting display apparatus described with reference to FIGS. 1 to 4. In the following description referring to FIGS. 5 to 8, the same reference numerals will be used for the same components, except for the additionally provided configuration, and their redundant descriptions will be omitted or briefly described.

Referring to FIGS. 5 to 8, a display panel 110 according to one or more other embodiments of the present disclosure may further include a non-opening optical pattern NBP disposed on an opening area (or emission area) of at least one pixel electrode AE among a plurality of subpixels SP1, SP2, SP3 and SP4. For example, the non-opening optical pattern NBP may be disposed between the pixel electrode AE and the emission layer EL.

The non-opening optical pattern NBP according to one or more other embodiments of the present disclosure may be formed of the same material as the low-reflection optical pattern portion LR-BA that defines opening areas (or emission areas) of the respective subpixels SP1, SP2, SP3 and SP4. For example, the non-opening optical pattern NBP may be disposed at a central portion of an opening area of the pixel electrode AE, or may be disposed to extend from the central portion in a first direction (or X-axis direction) or a second direction (or Y-axis direction).

Referring to FIGS. 5 and 6, the non-opening optical pattern NBP according to one or more other embodiments of the present disclosure may be formed as an island pattern disposed at a central portion of at least one pixel electrode AE among the plurality of subpixels SP1, SP2, SP3 and SP4. For example, the non-opening optical pattern NBP may be disposed at a central portion of the at least one pixel electrode AE in the first direction (or X-axis direction) and the second direction (or Y-axis direction), but embodiments of the present disclosure are not limited thereto.

The non-opening optical pattern NBP may be an island pattern having a square shape with the same length in the first direction and the second direction. For example, the non-opening optical pattern NBP may be an island pattern having a rectangular shape with different lengths in the first and second directions, or may have a circular or elliptical shape, but embodiments of the present disclosure are not limited thereto.

The non-opening optical pattern NBP may cover a portion of a central area of the pixel electrode AE to reduce an aperture ratio of an emission portion. In addition, the non-opening optical pattern NBP may reduce cell reflectivity of the emission area by absorbing a part of internal light that passes through the pixel electrode AE and is re-reflected by the common electrode CE.

The second subpixel SP2 among the plurality of subpixels SP1, SP2, SP3 and SP4 may be a white subpixel in which no color filter is disposed. The non-opening optical pattern NBP according to one or more other embodiments of the present disclosure may be selectively disposed in the second subpixel SP2 in which no color filter is disposed, thereby selectively reducing cell reflectivity of the second subpixel SP2 having relatively higher reflectivity than the other subpixels SP1, SP3 and SP4 due to the absence of a color filter. For example, the non-opening optical pattern NBP may be disposed in one or more selected subpixels among the plurality of subpixels SP1, SP2, SP3 and SP4. For example, the non-opening optical pattern NBP may be selectively disposed in the second subpixel SP2, which is a white subpixel, and the fourth subpixel SP4, which is a green subpixel, or may be disposed in all of the first to fourth subpixels SP1, SP2, SP3 and SP4, but embodiments of the present disclosure are not limited thereto.

The low-reflection optical pattern portion LR-BA according to one or more embodiments of the present disclosure may be disposed in the non-emission areas NEA of the respective subpixels SP1, SP2, SP3 and SP4, and the non-opening optical pattern NBP may be configured to be disposed as an island pattern at a central portion of an opening area of the pixel electrode AE. Through this configuration, the influence of process variations may be minimized or at least reduced, the aperture ratio and reflectivity of the emission area may be optimized, reflection caused by external light may be reduced, and light extraction efficiency may be improved.

Referring to FIG. 7, the non-opening optical pattern NBP according to one or more other embodiments of the present disclosure may be formed as a stripe pattern extending in the first direction (or X-axis direction) on at least one pixel electrode AE among the plurality of subpixels SP1, SP2, SP3 and SP4. For example, the non-opening optical pattern NBP may be disposed to extend in the first direction (or X-axis direction) at a central portion in the second direction (or Y-axis direction) of the at least one pixel electrode AE among the plurality of subpixels SP1, SP2, SP3 and SP4, but embodiments of the present disclosure are not limited thereto.

The non-opening optical pattern NBP may be a stripe pattern extending in the first direction with a constant width. For example, the non-opening optical pattern NBP illustrated in FIG. 7 may be configured to have a smaller width than one side length of the non-opening optical pattern NBP illustrated in FIG. 6, but embodiments of the present disclosure are not limited thereto.

The non-opening optical pattern NBP may be disposed at a central portion of the pixel electrode AE with respect to the second direction. One side of the non-opening optical pattern NBP may be connected to the low-reflection optical pattern portion LR-BA located on a left side in the first direction, and the other side of the non-opening optical pattern NBP may be connected to the low-reflection optical pattern portion LR-BA located on a right side in the first direction.

The non-opening optical pattern NBP may cover a portion of a central area of the pixel electrode AE across the first direction with respect to the second direction to reduce an aperture ratio of an emission portion. In addition, the non-opening optical pattern NBP may reduce cell reflectivity of the emission area by absorbing a part of internal light that passes through the pixel electrode AE and is re-reflected by the common electrode CE.

The non-opening optical pattern NBP according to one or more other embodiments of the present disclosure may be selectively disposed in the second subpixel SP2 in which no color filter is disposed, thereby selectively reducing cell reflectivity of the second subpixel SP2 having relatively higher reflectivity than the other subpixels SP1, SP3 and SP4 due to the absence of a color filter. For example, the non-opening optical pattern NBP may be disposed in one or more selected subpixels among the plurality of subpixels SP1, SP2, SP3 and SP4. For example, the non-opening optical pattern NBP may be selectively disposed in the second subpixel SP2, which is a white subpixel, and the fourth subpixel SP4, which is a green subpixel, or may be disposed in all of the first to fourth subpixels SP1, SP2, SP3 and SP4, but embodiments of the present disclosure are not limited thereto.

The low-reflection optical pattern portion LR-BA according to one or more embodiments of the present disclosure may be disposed in the non-emission areas NEA of the respective subpixels SP1, SP2, SP3 and SP4, and the non-opening optical pattern NBP may be configured as a stripe pattern crossing a central portion of an opening area of the pixel electrode AE in the second direction. Through this configuration, the influence of process variations may be minimized or at least reduced, the aperture ratio and reflectivity of the emission area may be optimized, reflection caused by external light may be reduced, and light extraction efficiency may be improved.

Referring to FIG. 8, the non-opening optical pattern NBP according to one or more other embodiments of the present disclosure may be formed as a stripe pattern extending in the second direction (or Y-axis direction) on at least one pixel electrode AE among the plurality of subpixels SP1, SP2, SP3 and SP4. For example, the non-opening optical pattern NBP may be disposed to extend in the second direction (or Y-axis direction) at a central portion in the first direction (or X-axis direction) of the at least one pixel electrode AE among the plurality of subpixels SP1, SP2, SP3 and SP4, but embodiments of the present disclosure are not limited thereto.

The non-opening optical pattern NBP may be a stripe pattern extending in the second direction with a constant width. For example, the non-opening optical pattern NBP illustrated in FIG. 8 may be configured to have a smaller width than one side length of the non-opening optical pattern NBP illustrated in FIG. 6 or a smaller width than that of the non-opening optical pattern NBP illustrated in FIG. 7, but embodiments of the present disclosure are not limited thereto.

The non-opening optical pattern NBP may be disposed at a central portion of the pixel electrode AE with respect to the first direction. One side of the non-opening optical pattern NBP may be connected to the low-reflection optical pattern portion LR-BA located on an upper side in the second direction, and the other side of the non-opening optical pattern NBP may be connected to the low-reflection optical pattern portion LR-BA located on a lower side in the second direction.

The non-opening optical pattern NBP may cover a portion of a central area of the pixel electrode AE across the second direction with respect to the first direction to reduce an aperture ratio of an emission portion. In addition, the non-opening optical pattern NBP may reduce cell reflectivity of the emission area by absorbing a part of internal light that passes through the pixel electrode AE and is re-reflected by the common electrode CE.

The non-opening optical pattern NBP according to one or more other embodiments of the present disclosure may be selectively disposed in the second subpixel SP2 in which no color filter is disposed, thereby selectively reducing cell reflectivity of the second subpixel SP2 having relatively higher reflectivity than the other subpixels SP1, SP3 and SP4 due to the absence of a color filter. For example, the non-opening optical pattern NBP may be disposed in one or more selected subpixels among the plurality of subpixels SP1, SP2, SP3 and SP4. For example, the non-opening optical pattern NBP may be selectively disposed in the second subpixel SP2, which is a white subpixel, and the fourth subpixel SP4, which is a green subpixel, or may be disposed in all of the first to fourth subpixels SP1, SP2, SP3 and SP4, but embodiments of the present disclosure are not limited thereto.

The low-reflection optical pattern portion LR-BA according to one or more embodiments of the present disclosure may be disposed in the non-emission areas NEA of the respective subpixels SP1, SP2, SP3 and SP4, and the non-opening optical pattern NBP may be configured as a stripe pattern crossing a central portion of an opening area of the pixel electrode AE in the first direction. Through this configuration, the influence of process variations may be minimized or at least reduced, the aperture ratio and reflectivity of the emission area may be optimized, reflection caused by external light may be reduced, and light extraction efficiency may be improved.

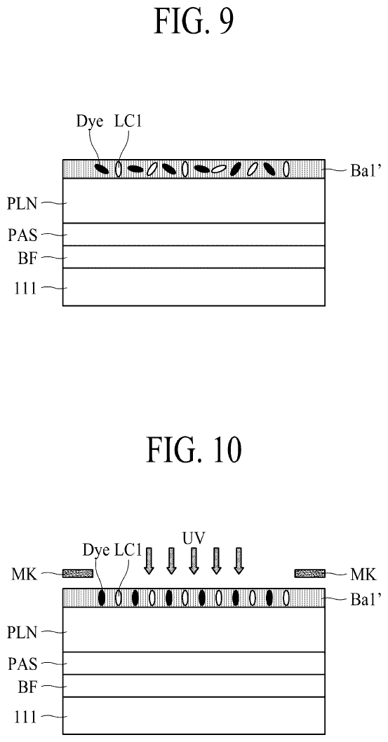

FIGS. 9 to 16 illustrate a method of manufacturing a low-reflection optical pattern portion in a display panel according to one or more embodiments of the present disclosure. FIGS. 9 to 16 illustrate a method for manufacturing the low-reflection optical pattern portion (or non-opening optical pattern) described with reference to FIGS. 3 to 8. FIGS. 9 to 16 illustrate a manufacturing method in which the low-reflection optical pattern portion LR-BA is formed on the planarization layer PLN in a non-emission area NEA. In the following description, the same reference numerals as those used in FIGS. 3 to 8 are assigned to the same components, and their redundant descriptions will be omitted or briefly described.

Referring to FIG. 9, a first optical coating layer Ba1′ may be formed by coating a material layer having anisotropic characteristics on the planarization layer PLN. The first optical coating layer Ba1′ may include an anisotropic material such as a reactive mesogen. For example, the first optical coating layer Ba1′ may be formed as a mixed structure of a liquid crystal material LC1 having photo-alignment characteristics and light blocking particles (Dye), and the light blocking particles (Dye) may include a black dye or a dichroic dye.

Referring to FIG. 10, a mask pattern MK may be disposed on the first optical coating layer Ba1′. For example, the mask pattern MK may define an opening area of the pixel electrode AE and may be configured to expose a portion corresponding to a non-emission area NEA. Thereafter, UV (ultraviolet) polarized light may be irradiated onto the first optical coating layer Ba1′, and the liquid crystal material LC1 and the light blocking particles Dye may be aligned according to photo-alignment induced by the UV polarization. For example, the liquid crystal material LC1 and the light blocking particles Dye of the first optical coating layer Ba1′ may be aligned to have a transmission axis of 90°.

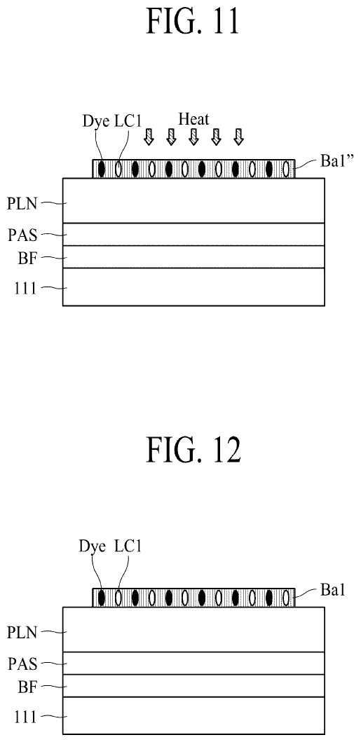

Referring to FIG. 11, the first optical coating layer Ba1′ may be selectively patterned corresponding to the mask pattern MK, thereby forming a first optical pattern layer Ba1″. Thereafter, the patterned first optical pattern layer Ba1″ may be cured through a thermal drying process.

Referring to FIG. 12, the first optical pattern layer Ba1 having a transmission axis of 90° may be formed on the planarization layer PLN. For example, the first optical pattern layer Ba1 may convert unpolarized light into linearly polarized light of 90°.

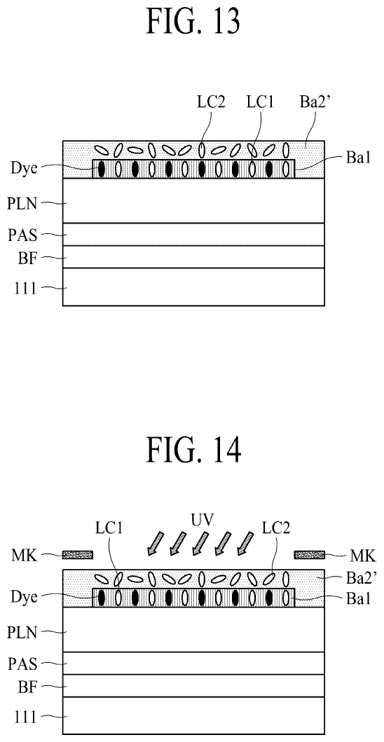

Referring to FIG. 13, a second optical coating layer Ba2′ may be formed by coating a material layer having anisotropic birefringent characteristics on the planarization layer PLN on which the first optical pattern layer Ba1 is formed. The second optical coating layer Ba2′ may include an anisotropic birefringent material such as a reactive mesogen. For example, the second optical coating layer Ba2′ may include a liquid crystal material LC2 having birefringence and photo-alignment characteristics.

Referring to FIG. 14, a mask pattern MK may be disposed on the second optical coating layer Ba2′. For example, the mask pattern MK may define an opening area of the pixel electrode AE and may be configured to expose a portion corresponding to a non-emission area NEA. Thereafter, UV (ultraviolet) polarized light may be irradiated onto the second optical coating layer Ba2′, and the liquid crystal material LC2 may be aligned according to photo-alignment induced by the UV polarization. For example, the liquid crystal material LC2 of the second optical coating layer Ba2′ may be aligned to have a transmission axis of 45° or 135° (or −45°).

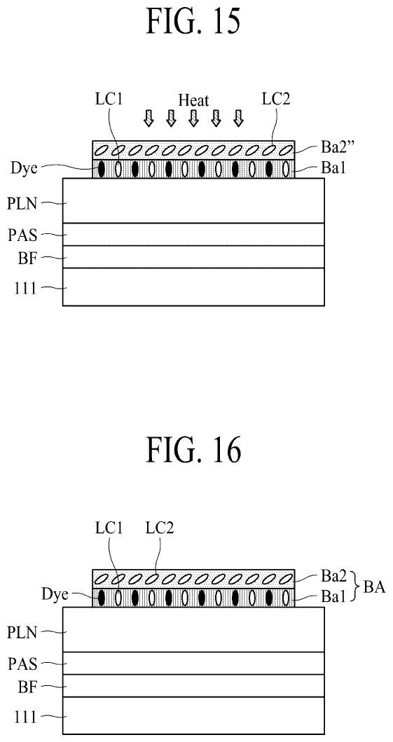

Referring to FIG. 15, the second optical coating layer Ba2′ may be selectively patterned corresponding to the mask pattern MK, thereby forming a second optical pattern layer Ba2″. Thereafter, the patterned second optical pattern layer Ba2″ may be cured through a thermal drying process.

Referring to FIG. 16, the second optical pattern layer Ba2 having a transmission axis of 45° may be formed on the first optical pattern layer Ba1. For example, the second optical pattern layer Ba2 may convert linear polarized light that has passed through the first optical pattern layer Ba1 into circular polarized light.

According to one or more embodiments of the present disclosure, the method of manufacturing the low-reflection optical pattern portion LR-BA may form the low-reflection optical pattern portion LR-BA through a conventional process of forming a bank layer that defines opening areas of pixel electrodes AE of the respective subpixels SP1, SP2, SP3 and SP4 and covers non-emission areas NEA. Accordingly, reflection caused by external light can be reduced and light extraction efficiency can be improved while minimizing or at least reducing the addition of mask processes. Therefore, reflection caused by external light in the light emitting display apparatus can be reduced and light extraction efficiency can be improved without increasing the manufacturing process or cost.

A light emitting display apparatus according to one or more embodiments of the present disclosure will be described below.

A light emitting display apparatus according to one or more embodiments of the present disclosure may include a substrate including a plurality of subpixels having an emission area and a non-emission area, a pixel circuit disposed in the non-emission area on the substrate, at least one insulating layer disposed on the pixel circuit, a planarization layer disposed on the at least one insulating layer, and a low-reflection optical pattern portion disposed on the planarization layer in the non-emission area and including a first optical pattern layer and a second optical pattern layer made of a material different from that of the first optical pattern layer.

According to one or more embodiments of the present disclosure, the first optical pattern layer may be disposed on the planarization layer, and the second optical pattern layer may be disposed on the first optical pattern layer.

According to one or more embodiments of the present disclosure, the first optical pattern layer and the second optical pattern layer may have different optical characteristics.

According to one or more embodiments of the present disclosure, the first optical pattern layer and the second optical pattern layer may have different transmission axes.

According to one or more embodiments of the present disclosure, the first optical pattern layer may have a linear polarization characteristic, and the second optical pattern layer may have a phase retardation characteristic.

According to one or more embodiments of the present disclosure, a phase retardation value of the second optical pattern layer may be λ/4.

According to one or more embodiments of the present disclosure, the first optical pattern layer may convert external light incident from the substrate into linearly polarized light, and the second optical pattern layer may convert the linearly polarized light passing through the first optical pattern layer into circularly polarized light to reduce reflection of the external light.

According to one or more embodiments of the present disclosure, the first optical pattern layer may include an anisotropic material, and the second optical pattern layer may include an anisotropic birefringent material.

According to one or more embodiments of the present disclosure, the first optical pattern layer and the second optical pattern layer may include a reactive mesogen.

According to one or more embodiments of the present disclosure, the first optical pattern layer and the second optical pattern layer may be formed through an alignment and curing process of the reactive mesogen according to ultraviolet (UV) light in different directions.

According to one or more embodiments of the present disclosure, the first optical pattern layer may further include light-blocking particles.

According to one or more embodiments of the present disclosure, the emission area may correspond to a light emitting element including a pixel electrode, an emission layer, and a common electrode of each of the subpixels, and the low-reflection optical pattern portion may be configured to define an opening area of the pixel electrode.

According to one or more embodiments of the present disclosure, the non-emission area may include a first non-emission area in which the pixel circuit is disposed and a second non-emission area between adjacent subpixels, and the low-reflection optical pattern portion may be disposed between the planarization layer and the emission layer in the first non-emission area, and may be disposed between an edge portion of the pixel electrode and the emission layer in the second non-emission area.

According to one or more embodiments of the present disclosure, at least one of the plurality of subpixels may further include a non-opening optical pattern disposed on the opening area of the pixel electrode, and the non-opening optical pattern may be made of the same material as the low-reflection optical pattern portion.

According to one or more embodiments of the present disclosure, the non-opening optical pattern may be an island pattern disposed at a central portion of the opening area of the pixel electrode.

According to one or more embodiments of the present disclosure, the non-opening optical pattern may extend from the central portion of the opening area of the pixel electrode in a first direction or in a second direction intersecting the first direction.

According to one or more embodiments of the present disclosure, the light emitting display apparatus may further include a color filter disposed between the at least one insulating layer and the planarization layer and corresponding to at least some of the plurality of subpixels, the non-opening optical pattern may overlap or may not overlap the color filter.

According to one or more embodiments of the present disclosure, the plurality of subpixels may include a white subpixel in which the color filter is not disposed, and the non-opening optical pattern may be disposed in the white subpixel.

According to one or more embodiments of the present disclosure, at least one metal layer included in the pixel circuit and the light emitting element may further include a low-reflection material layer.

According to one or more embodiments of the present disclosure, the light emitting display apparatus may further include a transmittance control film disposed on a rear surface of the substrate, the transmittance control film may include at least one of a transparent film and an absorbing film.

The above-described feature, structure, and effect of the present disclosure are included in one or more embodiments of the present disclosure, but are not limited to only one embodiment. Furthermore, the feature, structure, and effect described in one or more embodiments of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A light emitting display apparatus, comprising:
a substrate including a plurality of subpixels having an emission area and a non-emission area;
a pixel circuit disposed in the non-emission area on the substrate;
at least one insulating layer disposed on the pixel circuit;
a planarization layer disposed on the at least one insulating layer; and
a low-reflection optical pattern portion disposed on the planarization layer in the non-emission area, the low-reflection optical pattern portion including a first optical pattern layer made of a first material and a second optical pattern layer made of a second material different from the first material.

2. The light emitting display apparatus of claim 1, wherein the first optical pattern layer is disposed on the planarization layer, and wherein the second optical pattern layer is disposed on the first optical pattern layer.

3. The light emitting display apparatus of claim 1, wherein the first optical pattern layer and the second optical pattern layer have different optical characteristics.

4. The light emitting display apparatus of claim 3, wherein the first optical pattern layer and the second optical pattern layer have different transmission axes.

5. The light emitting display apparatus of claim 3, wherein the first optical pattern layer has a linear polarization characteristic, and the second optical pattern layer has a phase retardation characteristic.

6. The light emitting display apparatus of claim 5, wherein a phase retardation value of the second optical pattern layer is λ/4.

7. The light emitting display apparatus of claim 5, wherein the first optical pattern layer converts external light incident from the substrate into linearly polarized light, and wherein the second optical pattern layer converts the linearly polarized light passing through the first optical pattern layer into circularly polarized light to reduce a reflection of the external light.

8. The light emitting display apparatus of claim 1, wherein the first optical pattern layer includes an anisotropic material, and wherein the second optical pattern layer includes an anisotropic birefringent material.

9. The light emitting display apparatus of claim 7, wherein the first optical pattern layer and the second optical pattern layer include a reactive mesogen.

10. The light emitting display apparatus of claim 9, wherein the first optical pattern layer and the second optical pattern layer are formed through an alignment and curing process of the reactive mesogen according to ultraviolet (UV) light in different directions.

11. The light emitting display apparatus of claim 9, wherein the first optical pattern layer further includes light-blocking particles.

12. The light emitting display apparatus of claim 1, wherein the emission area corresponds to a light emitting element including a pixel electrode, an emission layer, and a common electrode of each of the plurality of subpixels, and wherein the low-reflection optical pattern portion is configured to define an opening area of the pixel electrode.

13. The light emitting display apparatus of claim 12, wherein the non-emission area includes a first non-emission area in which the pixel circuit is disposed and a second non-emission area between adjacent subpixels of the plurality of subpixels,
wherein the low-reflection optical pattern portion is disposed between the planarization layer and the emission layer in the first non-emission area, and
wherein the low-reflection optical pattern portion is disposed between an edge portion of the pixel electrode and the emission layer in the second non-emission area.

14. The light emitting display apparatus of claim 12, wherein at least one of the plurality of subpixels further includes a non-opening optical pattern disposed on the opening area of the pixel electrode, and wherein the non-opening optical pattern includes a same material as the low-reflection optical pattern portion.

15. The light emitting display apparatus of claim 14, wherein the non-opening optical pattern is an island pattern disposed at a central portion of the opening area of the pixel electrode.

16. The light emitting display apparatus of claim 14, wherein the non-opening optical pattern extends from a central portion of the opening area of the pixel electrode in a first direction or in a second direction intersecting the first direction.

17. The light emitting display apparatus of claim 14, further comprising a color filter disposed between the at least one insulating layer and the planarization layer,
wherein the color filter corresponds to one or more subpixels of the plurality of subpixels, and
wherein the non-opening optical pattern overlaps or does not overlap the color filter.

18. The light emitting display apparatus of claim 17, wherein the plurality of subpixels include a white subpixel in which the color filter is not disposed, and wherein the non-opening optical pattern is disposed in the white subpixel.

19. The light emitting display apparatus of claim 12, wherein at least one metal layer included in the pixel circuit and the light emitting element further includes a low-reflection material layer.

20. The light emitting display apparatus of claim 1, further comprising a transmittance control film disposed on a rear surface of the substrate,
wherein the transmittance control film includes at least one of a transparent film and an absorbing film.
